(19) United States
(12) Patent Application Publication
(10) Pub. No.: US 2008/0113157 A1
(43) Pub. Date: May 15, 2008

(54) Method for fabricating master stamper/imprinters for patterned recording media utilizing hybrid resist

(75) Inventors: Kim Y. Lee, Fremont, CA (US); Hong Ying Wang, Fremont, CA (US); Shih-Fu Lee, Fremont, CA (US); David S. Kuo, Pala Alto, CA (US); Koichi Wago, Sunnyvale, CA (US); Dieter K. Weller, San Jose, CA (US)

Correspondence Address: SEAGATE TECHNOLOGY LLC;c/o MCDERMOTT WILL & EMERY LLP, 600 13TH STREET, NW, WASHINGTON, DC, 20005-3096, US

(73) Assignee: SEAGATE TECHNOLOGY LLC

(21) Appl. No.: 11/595,894

(22) Filed: Nov. 13, 2006

(51) Int. Cl. G03F 7/00; B32B 3/00

(52) U.S. Cl. 428/141; 430/307; 430/296

(57) ABSTRACT

A method of fabricating a master stamper/imprinter for manufacturing a patterned recording medium by nano-imprint lithography comprises steps of: (a) providing a substrate having a surface; (b) forming a layer of a hybrid resist material on the surface, the resist layer having an exposed upper surface; (c) subjecting selected areas of the exposed upper surface of the resist layer to an energy beam to form therein a latent image of a topographical pattern to be formed in the resist layer and having a correspondence to a pattern to be formed in a patterned recording medium; and (d) developing the latent image into the topographical pattern in the resist layer, wherein only those areas of the resist layer which have received an energy beam exposure dose between a positive-tone threshold dose D₀ₚ and a negative-tone threshold dose D₀ₙ are developed.

### FIELD OF THE INVENTION

The present invention relates to an improved method for fabricating “master” stampers/imprinters utilized in the manufacture of patterned recording media and to the improved master stampers/imprinters obtained thereby. The invention enjoys particular utility in the manufacture of ultra-high areal recording density bit patterned magnetic media and servo patterned media, e.g., hard disk media utilized in computer-related applications.

### BACKGROUND OF THE INVENTION

Designers, manufacturers, and users of electronic computers and computing systems require reliable and efficient equipment for storage and retrieval of information in digital form. Conventional storage systems, such as magnetic disk drives, are typically utilized for this purpose and are well known in the art. However, the amount of information that is digitally stored continually increases, and designers and manufacturers of magnetic recording media work to increase the storage capacity of magnetic disks.

In conventional magnetic disk data/information storage, the data/information is stored in a continuous magnetic thin film overlying a substantially rigid, non-magnetic disk. Each bit of data/information is stored by magnetizing a small area of the thin magnetic film using a magnetic transducer (write head) that provides a sufficiently strong magnetic field to effect a selected alignment of the small area (magnetic grain) of the film. The magnetic moment, area, and location of the small area comprise a bit of binary information which must be precisely defined in order to allow a magnetic read head to retrieve the stored data/information.

Such conventional magnetic disk storage media based upon continuous magnetic recording films or layers incur a significant drawback/disadvantage which adversely affects realization of ultra-high areal density data/information storage. Specifically, the requirement for increased areal recording density necessitates a corresponding decrease in recording bit size or area. As a consequence, recording bit sizes of continuous film media have become extremely minute, e.g., on the order of nanometers (nm). In order to obtain a sufficient output signal from such minute bits, the saturation magnetization (Mₛ) and thickness of the film must be as large as possible. However, the magnetization quantity of such minute bits is extremely small, resulting in a loss of stored information due to magnetization reversal by “thermal fluctuation”, also known as the “superparamagnetic effect”.

The superparamagnetic effect is a major limiting factor in increasing the areal recording density of continuous film magnetic recording media. Superparamagnetism results from thermal excitations which perturb the magnetization of grains in a ferromagnetic material, resulting in unstable magnetization. As the grain size of magnetic media is reduced to achieve higher areal recording density, the superparamagnetic instabilities become more problematic. The superparamagnetic effect is most evident when the grain volume V is sufficiently small such that thermal energy demagnetizes the individual magnetic grains and the stored data bits are no longer stable. Consequently, as the magnetic grain size is decreased in order to increase the areal recording density, a threshold is reached at which stable data storage is no longer possible.

So-called “patterned” or “bit patterned” magnetic media (“BPM”) have been proposed as a means for overcoming the above-described problem of conventional continuous magnetic media associated with magnetization reversal via the superparamagnetic effect, e.g., as disclosed in U.S. Pat. No. 5,956,216, the entire disclosure of which is incorporated herein by reference. The term “bit patterned media” (“BPM”) generally refers to magnetic data/information storage and retrieval media wherein a plurality of discrete, independent regions of magnetic material which form discrete, independent magnetic elements that function as recording bits are formed on a non-magnetic substrate. Since the regions of ferromagnetic material comprising the magnetic bits or elements are independent of each other, mutual interference between neighboring bits is minimized. As a consequence, bit patterned magnetic media are advantageous vis-a-vis continuous magnetic media in reducing recording losses and noise arising from neighboring magnetic bits. In addition, patterning of the magnetic layer advantageously increases resistance to domain wall movement, i.e., enhances domain wall pinning, resulting in improved magnetic performance characteristics.

Generally, each magnetic bit or element has the same size and shape, and is composed of the same magnetic material as the other elements. The elements are arranged in a regular pattern over the substrate surface, with each element having a small size and desired magnetic anisotropy, so that, in the absence of an externally applied magnetic field, the magnetic moments of each discrete magnetic element are aligned along the same magnetic easy axis. The magnetic moment of each discrete magnetic element therefore has only two states: the same in magnitude but aligned in opposite directions. Each discrete magnetic element forms a single magnetic domain or bit and the size, area, and location of each domain is determined during the fabrication process.

During writing operation of patterned media, the direction of the magnetic moment of the single magnetic domain element or bit is flipped along the easy axis, and during reading operation, the direction of the magnetic moment of the single magnetic domain element or bit is sensed. While the direction of the magnetic easy axis of each of the magnetic domains, elements, or bits can be parallel or perpendicular to the surface of the domain, element, or bit, corresponding to conventional continuous longitudinal and perpendicular media, respectively, bit patterned media comprised of domains, elements, or bits with perpendicularly oriented magnetic easy axis are advantageous in achieving higher areal recording densities for the reasons given above.

Bit patterned media in disk form offer a number of advantages relative to conventional disk media. Specifically, the writing process is greatly simplified, resulting in much lower noise and lower error rate, thereby allowing much higher areal recording density. In bit patterned media, the writing process does not define the location, shape, and magnetization value of a bit, but merely flips the magnetization orientation of a patterned single domain magnetic structure. Writing of data can be essentially perfect, even when the transducer head deviates slightly from the intended bit location and partially overlaps neighboring bits, as long as only the magnetization direction of the intended bit is flipped. By contrast, in conventional magnetic disk media, the writing process must define the location, shape, and magnetization of a bit. Therefore, with such conventional disk media, if the transducer head deviates from the intended location, the head will write to part of the intended bit and to part of the neighboring bits. Another advantage of bit patterned media is that crosstalk between neighboring bits is reduced relative to conventional media, whereby areal recording density is increased. Each individual magnetic element, domain, or bit of a patterned medium can be tracked individually, and reading is less jittery than in conventional disks.

As utilized herein, the general expression “patterned recording media” is taken as encompassing different types of pattern formation and different types of recording media with patterned surfaces, including, but not limited to, servo-patterned magnetic and magneto-optical (“MO”) media, discrete track patterned media (“DTM”), bit patterned media (“BPM”), patterned read-only (“ROM”) media, wobble-groove patterned readable compact disk (“CD-R”), readable-writable compact disk (“CD-RW”) media, and digital video disk (“DVD”) media. Such media have been fabricated by a variety of processing techniques, including etching processing such as reactive ion etching, sputter etching, ion milling, and ion irradiation to form a pattern comprising magnetic and non-magnetic surface areas in a layer of magnetic material on a media substrate. Several of the these processing techniques have relied upon selective removal of portions of the layer of magnetic material to form the pattern of magnetic and non-magnetic surface areas; whereas others of the processing techniques have relied upon partial removal of selected areas of the media substrate on which the magnetic layer is formed, thereby resulting in different transducer head/media surface spacings having an effect similar to formation of a pattern of magnetic and non-magnetic surface areas in the layer of magnetic material. However, a drawback associated with each of these techniques is formation of topographical patterns in the surface of the media, engendering media performance concerns such as transducer head flyability and corrosion, e.g., due to uneven lubricant thickness and adhesion.

A recently developed, low cost alternative technique for fine dimension pattern/feature formation (i.e., sub-100 nm structures/features) in a substrate surface is thermally assisted nano-imprint lithography, as for example, described in U.S. Pat. Nos. 4,731,155; 5,772,905; 5,817,242; 6,117,344; 6,165,911; 6,168,845 B1; 6,190,929 B1; and U.S. Pat. No. 6,228,294 B1, the entire disclosures of which are incorporated herein by reference. A typical thermally assisted nano-imprint lithographic process for forming nano-dimensioned patterns/features in a substrate surface is illustrated with reference to the schematic, cross-sectional views of FIGS. 1 (A)-1 (D).

Referring to FIG. 1(A), shown therein is a stamper/imprinter 10 (also referred to in the related art as a “mold” or “template”) including a main (or support) body 12 having upper and lower opposed surfaces, with an imprinting layer 14 formed on the lower opposed surface. As illustrated, stamper/imprinter 14 includes a plurality of features 16 having a desired shape or surface contour. A workpiece 18 carrying a thin film layer 20 on an upper surface thereof is positioned below, and in facing relation to the molding layer 14. Thin film layer 20, of a thermoplastic polymer material, e.g., polymethylmethacrylate (PMMA), may be formed on the substrate/workpiece surface by any appropriate technique, e.g., spin coating.

Adverting to FIG. 1(B), shown therein is a compressive molding step, wherein stamper/imprinter 10 is pressed into the thin film layer 20 in the direction shown by arrow 22, so as to form depressed, i.e., compressed, regions 24. In the illustrated embodiment, features 16 of the imprinting layer 14 are not pressed all of the way into the thin film layer 20 and thus do not contact the surface of the underlying substrate 18. However, the top surface portions 24a of thin film 20 may contact depressed surface portions 16a of imprinting layer 14. As a consequence, the top surface portions 24a substantially conform to the shape of the depressed surface portions 16a, for example, flat. When contact between the depressed surface portions 16a of imprinting layer 14 and thin film layer 20 occurs, further movement of the imprinting layer 14 into the thin film layer 20 stops, due to the sudden increase in contact area, leading to a decrease in compressive pressure when the compressive force is constant.

FIG. 1(C) shows the cross-sectional surface contour of the thin film layer 20 following removal of stamper/imprinter 10. The imprinted thin film layer 20 includes a plurality of recesses formed at compressed regions 24 which generally conform to the shape or surface contour of features 16 of the molding layer 14. Referring to FIG. 1(D), in a next step, the surface-imprinted workpiece is subjected to processing to remove the compressed portions 24 of thin film 20 to selectively expose portions 28 of the underlying substrate 18 separated by raised features 26. Selective removal of the compressed portions 24 may be accomplished by any appropriate process, e.g., reactive ion etching (RIE) or wet chemical etching.

The above-described imprint lithographic processing is capable of providing sub-micron-dimensioned features, as by utilizing a stamper/imprinter 10 provided with patterned features 16 comprising pillars, holes, trenches, etc. Typical depths of features 16 range from about 5 to about 200 nm, depending upon the desired lateral dimension. The material of the imprinting layer 14 is typically selected to be hard relative to the thin film layer 20, the latter comprising a thermoplastic material which is softened when heated. Thus, materials which have been proposed for use as the imprinting layer 14 include metals, dielectrics, semiconductors, ceramics, and composite materials. Suitable materials for use as thin film layer 20 include thermoplastic polymers which can be heated to above their glass temperature, T_{g}, such that the material exhibits low viscosity and enhanced flow.

Referring to FIGS. 2(A)-2(E), shown therein, in simplified, schematic cross-sectional views, is a series of process steps for illustrating fabrication of bit patterned or servo patterned magnetic recording media utilizing thermal imprint lithography as part of the processing methodology.

In FIG. 2(A), a layer 70 of a thermoplastic polymer material, e.g., PMMA, covers a media substrate 72, e.g., of a suitable material (which substrate may comprise at least a surface layer of a magnetically soft material when the resultant medium is a perpendicular medium). Opposite the polymer layer 70 is a stamper/imprinter 74 which includes a patterned plurality of downwardly extending features 76, e.g., pillars as in the illustrated embodiment, of preselected dimensions and arrangement for forming a desired pattern in the polymer layer 70, e.g., a servo pattern or a discrete bit pattern. As indicated by the downwardly facing arrows in FIG. 2(A), the stamper/imprinter 74 is moved toward the polymer layer 70 to form an imprinted pattern therein which is a negative image of the pattern of the downwardly extending features 76 in the form of recesses 78, as shown in FIG. 2(B). During the imprinting process, the thermoplastic polymer layer 70 is typically maintained at an elevated temperature which facilitates the imprinting, i.e., at a temperature close to the melting or glass transition temperature T_{g} of the polymer material. The imprinted polymer layer is then subjected to further processing (e.g., etching) to effect complete removal of the bottom portions of the recesses 78 to thereby expose the surface of substrate 72, as shown in FIG. 2(C). Referring to FIG. 2(D), recesses 78 are then filled with a layer 80 of a magnetic recording material (or a plurality of stacked layers including seed, intermediate, etc., layers in addition to a layer of magnetic recording material). As shown in FIG. 2(E), excess material of layer 80 overfilling the recesses 78 is then removed via a planarization process, e.g., chemical-mechanical polishing (CMP), to leave a plurality of single elements or bits 82 each forming a single magnetic domain of a bit patterned medium.

Stampers/imprinters suitable for use in performing the foregoing patterning processes have conventionally been made from a number of materials such as etched Si wafers, etched quartz or glass, and electroformed metals, e.g., electroformed Ni, and may be manufactured by a sequence of steps as schematically illustrated in FIG. 3, which steps include providing a “master” comprised of a substantially rigid substrate with a patterned layer of a resist material thereon. The pattern, which is formed in the resist layer by conventional lithographic techniques, including, e.g., e-beam or laser beam exposure of selected areas of the resist, comprises a plurality of projections and depressions corresponding (in positive or negative image form, as necessary) to the desired pattern, e.g., a servo or discrete bit or track pattern, to be formed in the surface of the stamper/imprinter.

According to the process shown in FIG. 3, stampers/imprinters are made from the “master” by initially forming a thin, conformal layer of an electrically conductive material (e.g., Ni) over the patterned resist layer and then electroforming a substantially thicker (“blanket”) metal layer (e.g., Ni) on the thin layer of electrically conductive material, which electroformed blanket layer replicates the surface topography of the resist layer. Upon completion of the electroforming process, the stamper/imprinter is separated from the “master”.

Fabrication of the stampers/imprinters is a key factor in the processing methodology for patterned media such as bit, track, and servo patterned magnetic recording media. One process for fabricating stampers/imprinters for use-in manufacturing patterned media is illustrated in FIG. 4 and comprises steps of: e-beam writing a desired pattern in a resist layer formed on a Si wafer substrate to form a “master”, electroplating/electroforming Ni thereon to form a Ni “father”, electroplating/electroforming Ni on the “father” to generate at least one “mother”, and electroplating/electroforming Ni on the at least one “mother” to generate at least one “son”.

As indicated above, the escalating requirements for increased areal recording density of data/information storage media, e.g., magnetic media, necessitates the formation of media with ever higher bit densities, in turn requiring stampers/imprinters having extremely small pattern features. Electron beam (“e-beam”) lithography is capable of performing the extremely high resolution resist patterning necessary for fabricating the requisite stampers/imprinters. According to this methodology, a substrate surface is coated with a layer of e-beam resist and then exposed to patterns of e-beams, wherein the geometric arrangement (or pattern) and dosages of the e-beams defines the pattern to be formed in the resist layer. The exposed resist layer is then chemically processed, or developed, to either remove the exposed portions, as with “positive” resists, or to remove the unexposed portions, as with “negative” resists. The underlying substrate is then subjected to patterning utilizing the thus-formed patterned resist layer as a mask.

Although e-beam lithography can produce extremely high resolution patterns, the throughput rates of available e-beam processing apparatus are typically very low, since e-beams must be directed to each location on the resist surface in sequence. The slow speed characteristic of e-beam processing becomes very significant in the formation of stampers/imprinters for use with large area substrates, e.g., 95 mm diameter disks utilized in hard disk applications.

As is evident from the foregoing, it is necessary to provide master stamper/imprinters with bit array or line array patterns having a very high resolution in order to increase the areal recording density of the media fabricated by thermally assisted nano-imprint lithography. Unfortunately, however, for the reasons given above, resolution and product throughput rate are mutually competing characteristics of e-beam lithographic processing. As a consequence, the intensity of the e-beam is either reduced to increase resolution or a less sensitive resist is utilized. Increased resolution is achieved with a prohibitively high increase in e-beam writing times for large area substrates/workpieces (e.g., 95 mm diameter hard disks) and resultant low product throughput rates.

In view of the foregoing, there exists a need for improved methodology for fabricating master stampers/imprinters for use in thermally-assisted nano-imprint lithography which is free of the above-described problems, drawbacks, and disadvantages attendant upon the use of conventional e-beam resist patterning. Moreover, there exists a need for methodology which facilitates rapid, reliable, and cost-effective manufacture of improved master stampers/imprinters for use in rapid, reliable, accurate, and cost-effective patterning of a variety of types of recording media by means of thermally assisted nano-imprint lithography, including ultra-high areal recording density bit patterned magnetic media, discrete track media, servo patterned magnetic and magneto-optical (MO) recording media, and various types of CD and DVD recording media.

The present invention addresses and solves the aforementioned problems, drawbacks, and disadvantages associated with the use of conventional e-beam-based techniques for fabricating master stampers/imprinters, while maintaining full compatibility with the requirements of cost-effective manufacturing technology.

### DISCLOSURE OF THE INVENTION

An advantage of the present invention is an improved method of fabricating a master stamper/imprinter for use in manufacturing a patterned recording medium by means of nano-imprint lithography.

Another advantage of the present invention is an improved method of fabricating a master stamper/imprinter for use in manufacturing bit patterned recording media, track patterned recording media, and servo patterned recording media by means of nano-imprint lithography.

A further advantage of the present invention is improved master stampers/imprinters for use in manufacturing various types of patterned recording media by means of nano-imprint lithography.

Additional advantages and other aspects and features of the present invention will be set forth in the description which follows and in part will become apparent to those having ordinary skill in the art upon examination of the following or may be learned from the practice of the present invention. The advantages of the present invention may be realized and obtained as particularly pointed out in the appended claims.

According to an aspect of the present invention, the foregoing and other advantages are obtained in part by an improved method of fabricating a master stamper/imprinter for use in manufacturing a patterned recording medium by means of nano-imprint lithography, comprising steps of:

(a) providing a substrate having a surface;

(b) forming a layer of a hybrid resist material on the substrate surface, the hybrid resist layer having an exposed upper surface;

(c) subjecting selected areas of the exposed upper surface of the hybrid resist layer to an energy beam to form therein a latent image of a topographical pattern to be formed in the hybrid resist layer, the topographical pattern having a correspondence to a pattern to be formed in a patterned recording medium; and

(d) developing the latent image into the topographical pattern in the hybrid resist layer, wherein only those areas of the hybrid resist layer which have received an energy beam exposure dose between a positive-tone threshold dose D₀ₚ and a negative-tone threshold dose D₀ₙ are developed.

According to embodiments of the present invention, step (a) comprises providing a substrate comprised of a material selected from the group consisting of: metals, metal alloys, glass, ceramics, glass-ceramics, and composites and laminates of two or more of the recited materials; and step (b) comprises forming a layer of a hybrid resist material comprising at least one positive-tone component and at least one negative-tone component.

Embodiments of the present invention include those wherein step (b) comprises forming a layer of a hybrid resist material comprising at least one positive-tone component as a major proportion thereof and at least one negative-tone component as a minor proportion thereof, and the at least one negative-tone component comprises a cross-linking agent.

Further embodiments of the present invention include those wherein step (b) comprises forming a layer of a hybrid resist material comprising at least one negative-tone component as a major proportion thereof and at least one positive-tone component as a minor proportion thereof, and the at least one positive-tone component comprises at least one positively acting functional group.

In accordance with embodiments of the present invention, step (c) comprises subjecting the selected areas of the exposed upper surface of the hybrid resist layer to an electron beam, an X-ray beam, or a deep ultra-violet radiation beam.

Preferably, step (c) comprises subjecting the selected areas of the exposed upper surface of the hybrid resist layer to the energy beam to form therein a latent image of a pattern having a correspondence to a pattern to be formed in a servo patterned magnetic or magneto-optical (“MO”) medium, a discrete track patterned medium (“DTM”), a bit patterned medium (“BPM”), a patterned read-only medium (“ROM”), a wobble-groove patterned readable compact disk (“CD-R”) medium, a readable-writable compact disk (“CD-RW”) medium, or a digital video disk (“DVD”) medium.

According to embodiments of the present invention, step (c) comprises subjecting the selected areas of the exposed upper surface of the hybrid resist layer directly to the energy beam, whereby pairs of areas of the hybrid resist layer directly receive an energy beam exposure dose between the positive-tone threshold dose D₀ₚ and the negative-tone threshold dose D₀ₙ; and step (d) comprises developing the pairs of areas to form pairs of topographical features in the hybrid resist layer.

According to embodiments of the present invention, step (d) comprises contacting the exposed surface of the hybrid resist layer with a liquid developing solution comprising a solvent, and further comprises ultrasonically agitating the liquid developing solution.

Another aspect of the present invention is an improved method of fabricating a master stamper/imprinter for use in manufacturing a patterned recording medium by means of nano-imprint lithography, comprising steps of:

(a) providing a substrate having a surface, the substrate comprising a material selected from the group consisting of: metals, metal alloys, glass, ceramics, glass-ceramics, and composites and laminates of two or more of the recited materials;

(b) forming a layer of a hybrid resist material on the substrate surface, the hybrid resist layer having an exposed upper surface and comprising at least one positive-tone component and at least one negative-tone component;

(c) subjecting selected areas of the exposed upper surface of the hybrid resist layer to an energy beam selected from the group consisting of an electron beam, an X-ray beam, and a deep ultra-violet radiation beam, to form therein a latent image of a topographical pattern to be formed in the hybrid resist layer, the topographical pattern having a correspondence to a pattern to be formed in a patterned recording medium; and

(d) developing the latent image into the topographical pattern in the hybrid resist layer, wherein only those areas of the hybrid resist layer which have received an energy beam exposure dose between a positive-tone threshold dose D₀ₚ and a negative-tone threshold dose D₀ₙ are developed.

Preferred embodiments of the present invention include those wherein step (c) comprises subjecting the selected areas of the exposed upper surface of the hybrid resist layer to the energy beam to form therein a latent image of a pattern having a correspondence to a pattern to be formed in a servo patterned magnetic or magneto-optical (“MO”) medium, a discrete track patterned medium (“DTM”), a bit patterned medium (“BPM”), a patterned read-only medium (“ROM”), a wobble-groove patterned readable compact disk (“CD-R”) medium, a readable-writable compact disk (“CD-RW”) medium, or a digital video disk (“DVD”) medium, selected areas of the exposed upper surface of the hybrid resist layer are directly exposed to the energy beam, whereby pairs of selected areas of the hybrid resist layer directly receive an energy beam exposure dose between the positive-tone threshold dose D₀ₚ and the negative-tone threshold dose D₀ₚ; and step (d) comprises developing the pairs of areas to form pairs of topographical features in the hybrid resist layer.

Yet another aspect of the present invention is patterned recording media fabricated according to the above-described process.

Additional advantages and aspects of the present invention will become readily apparent to those skilled in the art from the following detailed description, wherein embodiments of the present invention are shown and described, simply by way of illustration of the best mode contemplated for practicing the present invention. As will be described, the present invention is capable of other and different embodiments, and its several details are susceptible of modification in various obvious respects. Accordingly, the drawings and description are to be regarded as illustrative in nature, and not as limitative.

### BRIEF DESCRIPTION OF THE DRAWINGS

The following detailed description of the embodiments of the present invention can best be understood when read in conjunction with the following drawings, in which the various features are not necessarily drawn to scale but rather are drawn as to best illustrate the pertinent features, wherein:

FIGS. 1(A)-1(D) illustrate, in simplified cross-sectional schematic views, a process for performing thermally assisted nano-imprint lithography of a thin film on a substrate (workpiece) surface for forming nano-dimensioned features in the surface of the substrate, according to the conventional art;

FIGS. 2(A)-2(E) illustrate, in simplified, schematic cross-sectional views, a series of process steps for fabrication of bit patterned or servo patterned recording media utilizing thermal imprint lithography as part of the processing methodology;

FIG. 3 illustrates, in simplified, schematic cross-sectional views, a series of process steps for fabrication of a stamper/imprinter utilizing a “master” stamper/imprinter, according to the conventional art;

FIG. 4 illustrates, in simplified, schematic cross-sectional views, a series of process steps for fabrication of “father”, “mother”, and “son” stamper/imprinters originating from a “master” stamper/imprinter;

FIG. 5 is a graph illustrating the development contrast curve of an exemplary hybrid resist having both positive-tone and negative-tone characteristics; and

FIG. 6 schematically illustrates the “frequency doubling” effect afforded by hybrid resist materials when exposed to an energy beam via an apertured mask.

### DESCRIPTION OF THE INVENTION

The present invention addresses and solves the above-described problems, disadvantages, and drawbacks associated with nano-imprint lithographic patterning methodologies utilized in the fabrication of master stamper/imprinters used in the manufacture of various types of patterned recording media, including, for example, bit, discrete track, and servo patterned hard disk magnetic media, while maintaining full capability with all aspects of automated manufacturing processing for formation of patterned media. Specifically, the inventive methodology addresses and solves the problem of low product throughput rate when performing high resolution e-beam processing for lithographic patterning of resist materials with ultra-small features necessitated by the requirement for further increase in areal recording density to the Tbit/in² range. Advantageously, the inventive methodology can be practiced in a cost-effective manner without requiring capital-intensive processing techniques and instrumentalities, while minimizing the requisite number of topographical patterning steps. Further, as has been indicated above, the methodology afforded by the present invention enjoys diverse utility in the manufacture of various and different types of recording media and devices requiring pattern formation.

A key feature of the present invention is use of hybrid resist materials in place of the single-tone resist materials utilized according to conventional practices for forming topographical patterns of master stampers/imprinters. Hybrid resist materials, such as described in U.S. Pat. Nos. 6,190,829 B1 and 6,338,934 B1, the disclosures of which are incorporated herein by reference, comprise at least one positive-tone component and at least one negative-tone component. For example, a hybrid resist material may comprise a major proportion of the positive-tone component(s) and a minor proportion of the negative-tone component(s), e.g., in the form of at least one cross-linking agent. Alternatively, a hybrid resist material may comprise a major proportion of the negative-tone component(s) and a minor proportion of the positive-tone component(s), e.g., in the form of at least one positively acting functional group. Hybrid resist materials are advantageously capable of forming patterns with smaller feature sizes than are presently available through scaling of lithographic techniques via use of shorter wavelengths and variation of numerical aperture (NA) size, and thus are useful in forming stampers/imprinters with the very small topographical features required for fabricating ultra-high areal density patterned recording media.

Referring to FIG. 5, shown therein is a graph illustrating the development contrast curve of an exemplary hybrid resist having both positive-tone and negative-tone characteristics, formed by adding a minor amount of a negative-tone component, i.e., a cross-linking agent, to a major amount of a positive-tone component, as a function of exposure dose (e-beam, X-ray beam, or DUV beam). When the exposure dose (ED) received by a particular area of the hybrid resist material is below a threshold dose D₀ₚ of the positive-tone component, i.e., ED<D₀ₚ, that area will not develop and remains insoluble upon contact with the developing solution. Similarly, when the exposure dose received by a particular area of the hybrid resist material is above a threshold dose D₀ₙ of the negative-tone component, i.e., ED>Dₒₙ, that area will be cross-linked and will not develop, remaining insoluble upon contact with the developing solution. However, when the exposure dose received by a particular area of the hybrid resist material is between the threshold dose D₀ₚ of the positive-tone component and the threshold dose D₀ₙ of the negative-tone component, i.e., D₀ₚ<ED<D₀ₙ, that area will develop and dissolve upon contact with the developing solution.

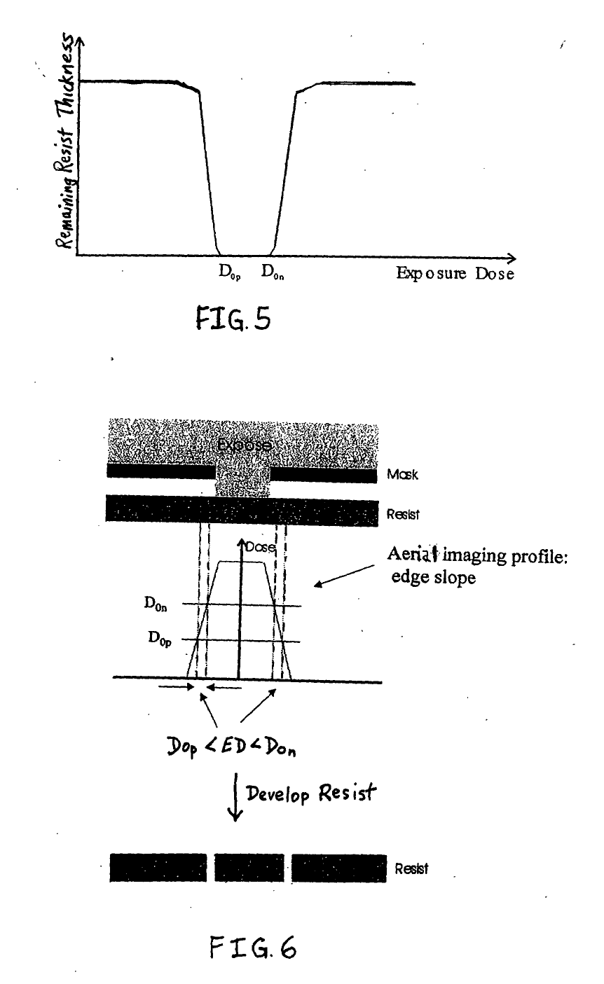

Adverting to FIG. 6, shown therein, in schematic form, is an illustrative example of the “frequency doubling” effect advantageously afforded by hybrid resist materials when exposed to an energy beam according to an illustrative, but non-limitative embodiment of the present invention. The frequency doubling effect occurs when selected portions or areas of a layer of a hybrid resist material are exposed to an energy beam (e.g., an electron beam, X-ray beam, or deep ultra-violet beam), some spreading of the beam occurs, as by diffraction, scattering, etc., whereby the exposure dose received by the selected portions or areas varies across the extent of the portions or areas. In the case of a hybrid resist material such as described above and comprising a major proportion of a positive-tone component and a minor proportion of a negative-tone component (e.g., a cross-linking agent), a consequence of the unequal exposure dose received by the layer of hybrid resist material is that only those areas where the received exposure dosage is between the threshold dose D₀ₚ of the positive-tone component and the threshold dose D₀ₙ of the negative-tone component, i.e., D₀ₚ<ED<D₀ₙ, will develop and dissolve upon contact with the developing solution. As may be seen from the edge slope of the aerial imaging profile shown in FIG. 6, only a pair of narrow width lines or regions, each laterally offset a small distance from the aperture perimeter, receive the appropriate exposure dosage (D₀ₚ<ED<D₀ₙ), resulting in development (i.e., formation) of a pair of very narrow openings or trenches in the resist layer. As may be evident from the figure, the width of the resultant openings or trenches depends upon the edge slope of the aerial imaging profile. A similar frequency doubling effect occurs with hybrid resist materials comprising a major proportion of a negative-tone component and a minor proportion of a positive-tone component.

Not shown in FIG. 6, for illustrative simplicity, is a substrate on which the hybrid resist layer is formed. When forming master stampers/imprinters the substrate comprises a material selected from the group consisting of: metals, metal alloys, glass, ceramics, glass-ceramics, and composites and laminates of two or more of the these materials. The exposure pattern may have a correspondence to a pattern to be formed in a servo patterned magnetic or magneto-optical (“MO”) medium, a discrete track patterned medium (“DTM”), a bit patterned medium (“BPM”), a patterned read-only medium (“ROM”), a wobble-groove patterned readable compact disk (“CD-R”) medium, a readable-writable compact disk (“CD-RW”) medium, or a digital video disk (“DVD”) medium. Development of the exposed resist layer may comprise contacting the exposed surface of the hybrid resist layer with a liquid developing solution comprising a solvent, and may further comprise ultrasonically agitating the liquid developing solution.

The above-described characteristic of hybrid resist materials may be utilized to advantage in high resolution fabrication of master stamper/imprinters employed in the manufacture of various types of patterned recording media as indicated above, wherein the master stampers/imprinters comprise a topographically patterned imprinting surface with features including a plurality of nano-dimensioned, spaced-apart projections and depressions. Specifically, the use of hybrid resist materials: (1) facilitates high resolution formation of pattern features with ultra-fine features; and (2) significantly increases product throughput rates via the “frequency doubling” effect described above, wherein exposure of the resist layer through an aperture mask yields two features in the resist layer for each aperture.

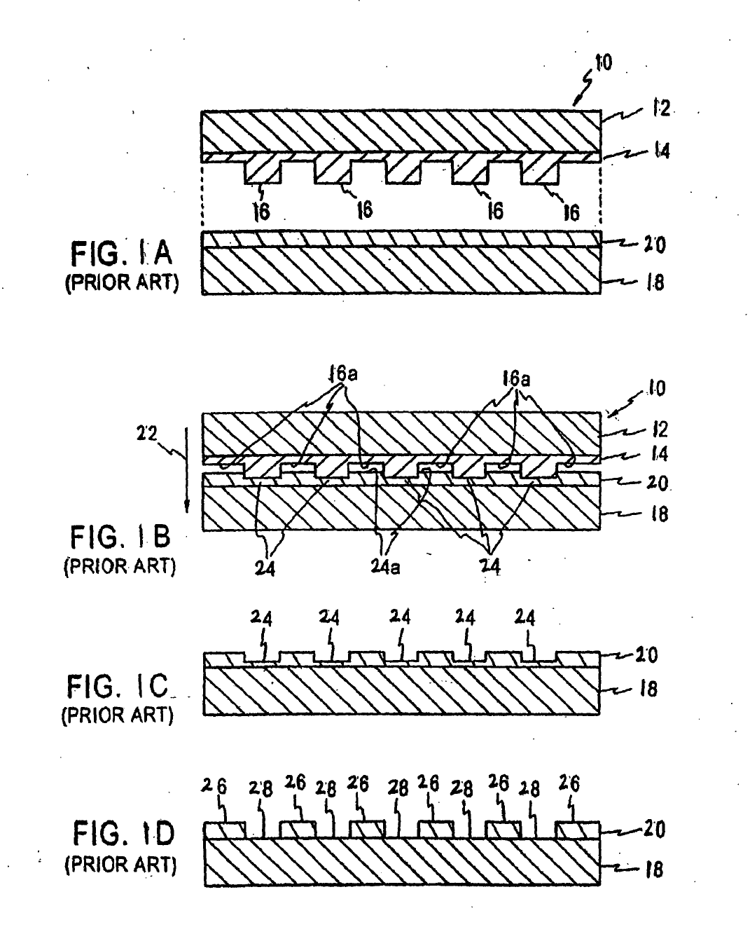

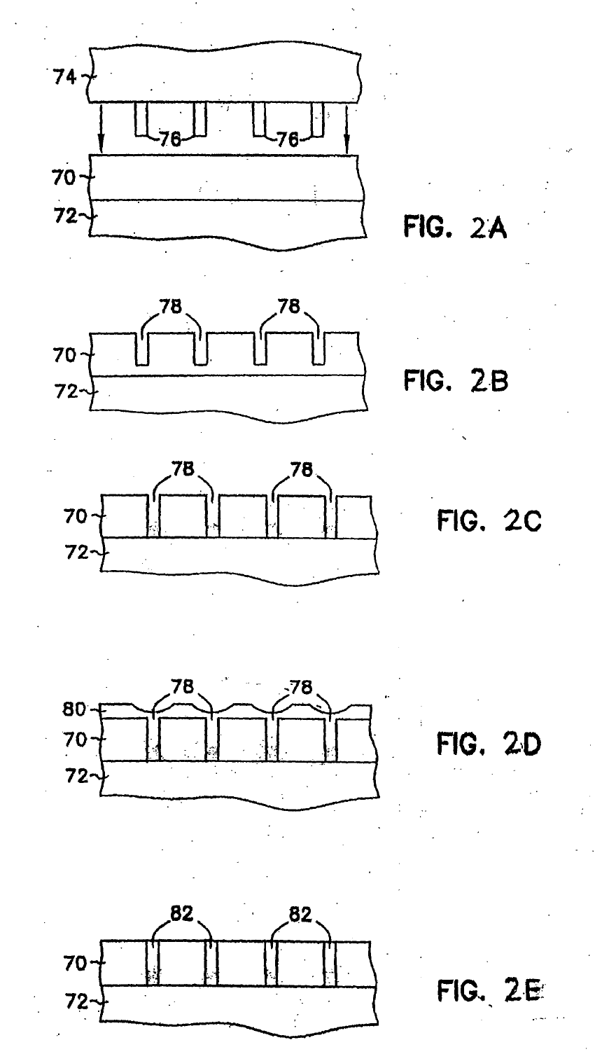

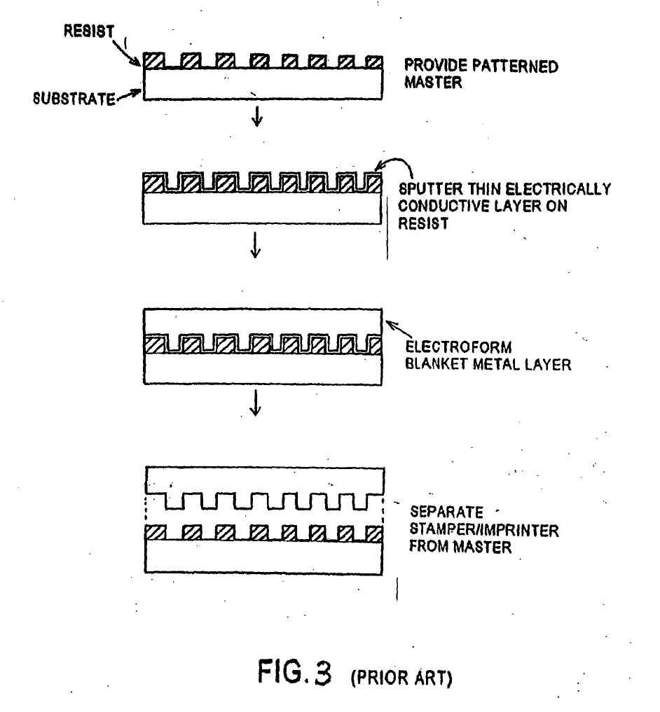

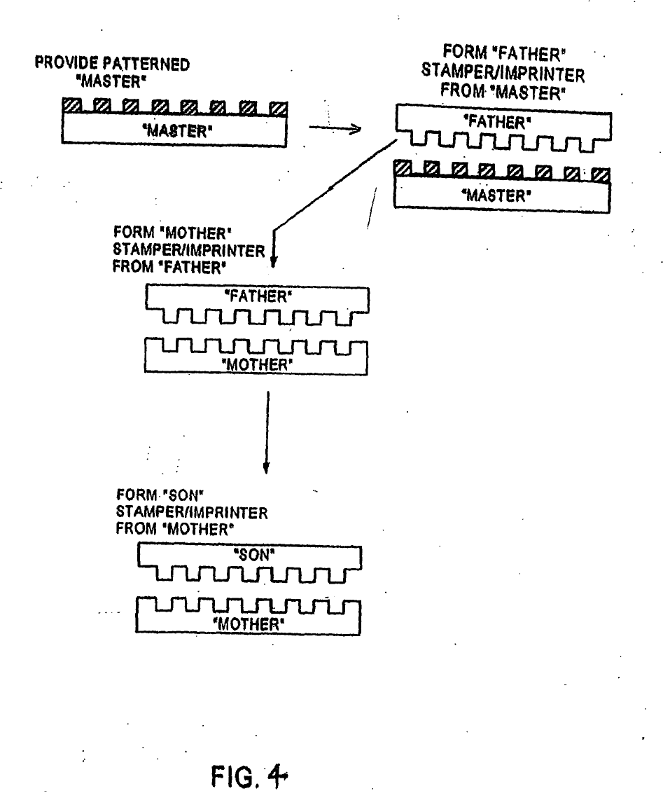

Master stampers/imprinters formed according to the inventive methodology may be utilized for forming hard-surfaced stampers/imprinters utilized for patterning recording media according to nano-imprint lithography, as described above in reference to FIGS. 1(A)-1(D) and FIGS. 2(A)-2(E). A family of hard surfaced of “father”, “mother”, and “son” stamper/imprinters originating from a “master” stamper/imprinter fabricated according to the inventive methodology utilizing a hybrid resist material may be fabricated according to the process sequences shown in FIGS. 3 and 4 and described above.

Whereas the “frequency doubling” process as disclosed above is readily adapted for forming a periodic patterns of lines as required for fabricating master stampers/imprinters utilized in imprinting discrete track patterned (“DTM”) media, bit patterned media (“BPM”) can be fabricated utilizing a pair of line-patterned master stampers/imprinters formed according to the above-described hybrid resist process, wherein a “cross-imprinting” process is performed by orienting the pair of line-patterned master stampers/imprinters at an angle to each other, whereby small areas (bits) are defined at the intersections of the line patterns.

In the previous description, numerous specific details are set forth, such as specific materials, structures, reactants, processes, etc., in order to provide a better understanding of the present invention. However, the present invention can be practiced without resorting to the details specifically set forth. In other instances, well-known processing materials and techniques have not been described in detail in order not to unnecessarily obscure the present invention.

Only the preferred embodiments of the present invention and but a few examples of its versatility are shown and described in the present disclosure. It is to be understood that the present invention is capable of use in other combinations and environments and is susceptible of changes and/or modifications within the scope of the inventive concept as expressed herein.

What is claimed is:

1. A method of fabricating a master stamper/imprinter for use in manufacturing a patterned recording medium by means of nano-imprint lithography, comprising steps of:
(a) providing a substrate having a surface;
(b) forming a layer of a hybrid resist material on said substrate surface, said hybrid resist layer having an exposed upper surface;
(c) subjecting selected areas of said exposed upper surface of said hybrid resist layer to an energy beam to form therein a latent image of a topographical pattern to be formed in said hybrid resist layer, said topographical pattern having a correspondence to a pattern to be formed in a patterned recording medium; and
(d) developing said latent image into said topographical pattern in said hybrid resist layer, wherein only those areas of said hybrid resist layer which have received an energy beam exposure dose between a positive-tone threshold dose D₀ₚ and a negative-tone threshold dose D₀ₙ are developed.

2. The method as in claim 1, wherein:
step (a) comprises providing a substrate comprised of a material selected from the group consisting of: metals, metal alloys, glass, ceramics, glass-ceramics, and composites and laminates of two or more of the recited materials.

3. The method as in claim 1, wherein:
step (b) comprises forming a layer of a hybrid resist material comprising at least one positive-tone component and at least one negative-tone component.

4. The method as in claim 3, wherein:
step (b) comprises forming a layer of a hybrid resist material comprising at least one positive-tone component as a major proportion thereof and at least one negative-tone component as a minor proportion thereof.

5. The method as in claim 4, wherein:
said at least one negative-tone component comprises a cross-linking agent.

6. The method as in claim 3, wherein:
step (b) comprises forming a layer of a hybrid resist material comprising at least one negative-tone component as a major proportion thereof and at least one positive-tone component as a minor proportion thereof.

7. The method as in claim 6, wherein:
said at least one positive-tone component comprises at least one positively acting functional group.

8. The method as in claim 1, wherein:
step (c) comprises subjecting said selected areas of said exposed upper surface of said hybrid resist layer to an electron beam.

9. The method as in claim 1, wherein:
step (c) comprises subjecting said selected areas of said exposed upper surface of said hybrid resist layer to an X-ray beam.

10. The method as in claim 1, wherein:
step (c) comprises subjecting said selected areas of said exposed upper surface of said hybrid resist layer to a deep ultra-violet radiation beam.

11. The method as in claim 1, wherein:
step (c) comprises subjecting said selected areas of said exposed upper surface of said hybrid resist layer to said energy beam to form therein a latent image of a pattern having a correspondence to a pattern to be formed in a servo patterned magnetic or magneto-optical (“MO”) medium, a discrete track patterned medium (“DTM”), a bit patterned medium (“BPM”), a patterned read-only medium (“ROM”), a wobble-groove patterned readable compact disk (“CD-R”) medium, a readable-writable compact disk (“CD-RW”) medium, or a digital video disk (“DVD”) medium.

12. The method as in claim 1 1, wherein:
step (c) comprises subjecting said selected areas of said exposed upper surface of said hybrid resist layer directly to said energy beam.

13. The method as in claim 12, wherein:
pairs of areas of said hybrid resist layer directly receive an energy beam exposure dose between said positive-tone threshold dose D₀ₚ and said negative-tone threshold dose Dₒₙ.

14. The method as in claim 13, wherein:
step (d) comprises developing said pairs of areas to form pairs of topographical features in said hybrid resist layer.

15. The method as in claim 1, wherein:
step (d) comprises contacting said exposed surface of said hybrid resist layer with a liquid developing solution comprising a solvent.

16. The method as in claim 15, wherein:
step (d) further comprises ultrasonically agitating said liquid developing solution.

17. A method of fabricating a master stamper/imprinter for use in manufacturing a patterned recording medium by means of nano-imprint lithography, comprising steps of:
(a) providing a substrate having a surface, said substrate comprising a material selected from the group consisting of: metals, metal alloys, glass, ceramics, glass-ceramics, and composites and laminates of two or more of the recited materials;
(b) forming a layer of a hybrid resist material on said substrate surface, said hybrid resist layer having an exposed upper surface and comprising at least one positive-tone component and at least one negative-tone component;
(c) subjecting selected areas of said exposed upper surface of said hybrid resist layer to an energy beam selected from the group consisting of an electron beam, an X-ray beam, and a deep ultra-violet radiation beam, to form therein a latent image of a topographical pattern to be formed in said hybrid resist layer, said topographical pattern having a correspondence to a pattern to be formed in a patterned recording medium; and
(d) developing said latent image into said topographical pattern in said hybrid resist layer, wherein only those areas of said hybrid resist layer which have received an energy beam exposure dose between a positive-tone threshold dose D₀ₚ and a negative-tone threshold dose D₀ₙ are developed.

18. The method as in claim 17, wherein:
step (c) comprises subjecting said selected areas of said exposed upper surface of said hybrid resist layer to said energy beam to form therein a latent image of a pattern having a correspondence to a pattern to be formed in a servo patterned magnetic or magneto-optical (“MO”) medium, a discrete track patterned medium (“DTM”), a bit patterned medium (“BPM”), a patterned read-only medium (“ROM”), a wobble-groove patterned readable compact disk (“CD-R”) medium, a readable-writable compact disk (“CD-RW”) medium, or a digital video disk (“DVD”) medium.

19. The method as in claim 18, wherein:
step (c) comprises subjecting said selected areas of said exposed upper surface of said hybrid resist layer directly to said energy beam, and pairs of selected areas of said hybrid resist layer directly receive an energy beam exposure dose between said positive-tone threshold dose D₀ₚ and said negative-tone threshold dose D₀ₙ; and
step (d) comprises developing said pairs of areas to form pairs of topographical features in said hybrid resist layer.

20. A patterned recording medium fabricated according to the process of claim 19.
